(19) United States
(12) Patent Application Publication
(10) Pub. No.: US 2023/0080804 A1
(43) Pub. Date: Mar. 16, 2023

(54) TRANSIT

(71) Applicant: ROXTEC AB, Karlskrona (SE)

(72) Inventor: Daniel STRÄNG, Karlskrona (SE)

(73) Assignee: ROXTEC AB, Karlskrona (SE)

(21) Appl. No.: 17/796,299

(22) PCT Filed: Feb. 2, 2021
(86) PCT No.: PCT/SE2021/050076

§ 371 Date: Jul. 29, 2022

(30) Foreign Application Priority Data
Feb. 4, 2020 (SE) 2050114-4

(51) Int. Cl. H02G 3/22; F16L 5/08; F16L 5/10; H03F 3/02

(52) U.S. Cl. CPC H02G 3/22; F16L 5/08; F16L 5/10; H03F 3/02

(57) ABSTRACT

A transit for cables and/or pipes through a partition. The transit comprises one or more parts made of a rubber or plastic material. Said at least one or more parts are made of a dissipative rubber or plastic material. For an explosive environment, the use of dissipative materials reduce the risk of an explosion due to electrostatic charges.

### TECHNICAL FIELD

The present invention concerns a transit, seal or lead-through for cables or pipes.

### BACKGROUND

In the prior art there are cable or pipe transitions or the like having a frame, inside which a number of modules to receive cables, wires or pipes are placed. The frame is normally fastened in an opening of a partition. The modules are made of an elastic material e.g. rubber or plastics and are thus compressible. Inside the frame normally a number of modules are received side by side in one or more rows together with some kind of compression unit. The compression unit is placed between the frame and the modules in such a way that when the compression unit is expanded the compressible modules will be compressed around the cables, wires or pipes. For ease of description the expression “cable” is mainly used in this description, but it should be construed broadly and a person skilled in the art realizes that it normally also covers pipes or wires.

Another type of seal, cable transition, pipe penetration etc. has a general cylindrical form and is to be received in a sleeve in a wall or an opening in a wall. To function in the desired way, the seal should fit snugly into the sleeve or the opening of the wall in which it is received and the seal should be adaptable to the actual mounting dimension. The mounting dimension is dictated by the inner diameter of the sleeve or the opening. The seal has a cylindrical compressible body, which is compressed axially between fittings at the opposite ends of the compressible body. By the axial compression the cylindrical body will expand radially both inwards and outwards.

Seals or transitions of both the above kinds are used for sealing in many different environments, such as for cabinets, technical shelters, junction boxes and machines. They are used in different industrial environments, such as automotive, telecom, power generation and distribution, as well as marine and offshore. The seals or transition may have to seal against fluid, gas, fire rodents, termites, dust, moisture etc., and may receive cables or wires for electricity, communication, computers etc., pipes for different gases or liquids such as water, compressed air, hydraulic fluid and cooking gas or wires for load retention.

Furthermore, the pipes, wires or cables received may have different outer diameters and, thus, the module or compressible body should be adaptable to cables, wires or pipes having different outer diameters. The parts receiving a single cable etc. of both the types described above often have a pack of peelable layers or sheets on the inside. The layers or sheets are peeled off until the inner diameter of the part is adapted to the outer diameter of the cable to be received in said part. The sheets adhere strong enough to each other to stay together and at the same time loose enough to enable the sheets to be peeled off from the stack, either one-by-one or a number of sheets together.

### SUMMARY

In many situations, there is a need to connect metal parts of a seal or transition to earth. This can for instance be done to hinder disturbances to spread in or along a cable. In spaces where there is a risk of an explosion, it is used to avoid danger of ignition due to electrostatic charges, by avoidance of a build-up of electrostatic charge on external enclosures, parts of enclosures or surfaces related to transits.

For explosive environments there are directives and standards that states that a particular size of surface area consisting of non-metallic should not be exceeded and that no external conductive parts not connect to earth should be used.

In view of the above one object of the present invention is to reduce non-metallic surfaces and to eliminate metal parts not connected to earth. This object is fulfilled by a transit according to the main claim. Embodiments of the invention are defined in the dependent claims.

Dissipative material allows electric charges to flow more slowly through the material than normal conductive material. It could be said that electric charges flow in a more controlled way than for normal conductive material. Dissipative materials allow the charges to flow to ground more slowly in a more controlled manner than with normal conductive materials. One feature often used in definition of dissipative material is that it has a resistance of 10⁶ to 10¹² ohm.

Further objects and advantages of the present invention will be obvious to a person skilled in the art when reading the detailed description below.

### BRIEF DESCRIPTION OF THE DRAWINGS

The invention will be described further below by way of examples and with reference to the enclosed drawings. In the drawings:

FIG. 1 is a perspective view of a transit placed in a partition,

FIG. 2 is a perspective view of an alternative transit,

FIG. 3 is an exploded view of a module,

FIG. 4 is a side view of a compression unit, that can be used in the transitions of FIGS. 1 and 2,

FIG. 5 is a perspective view of a cylindrical transit,

FIG. 6 is a perspective view of an alternative cylindrical transit,

FIG. 7 is an exploded view of a further transit, and

FIG. 8 is a section view of the transit of FIG. 7, as mounted in an opening of a partition.

### DETAILED DESCRIPTION

A module 2 is provided comprising two base parts 9. An axial through opening is formed in the centre of the module 2. Said axial through opening is formed by means of a semi-cylindrical recess in respective base part 9. Thus, an axial through opening is formed in that two base parts 9 are placed against each other with the semi-cylindrical recesses facing each other.

A number of peelable layers 10 are placed on the inside of the axial through opening of the module 2. The layers 10 of the module 2 are peeled off to adapt the inner diameter of the through opening of the module 2 to the outer diameter of a cable or pipe to be received inside the module 2. A blind 11 placed in the through opening of the module 2 is removed before receiving a cable or pipe.

The base parts 9 of the module 2 are made of a dissipative rubber or plastic material. Also the layers 10 may be made of a dissipative rubber or plastic material.

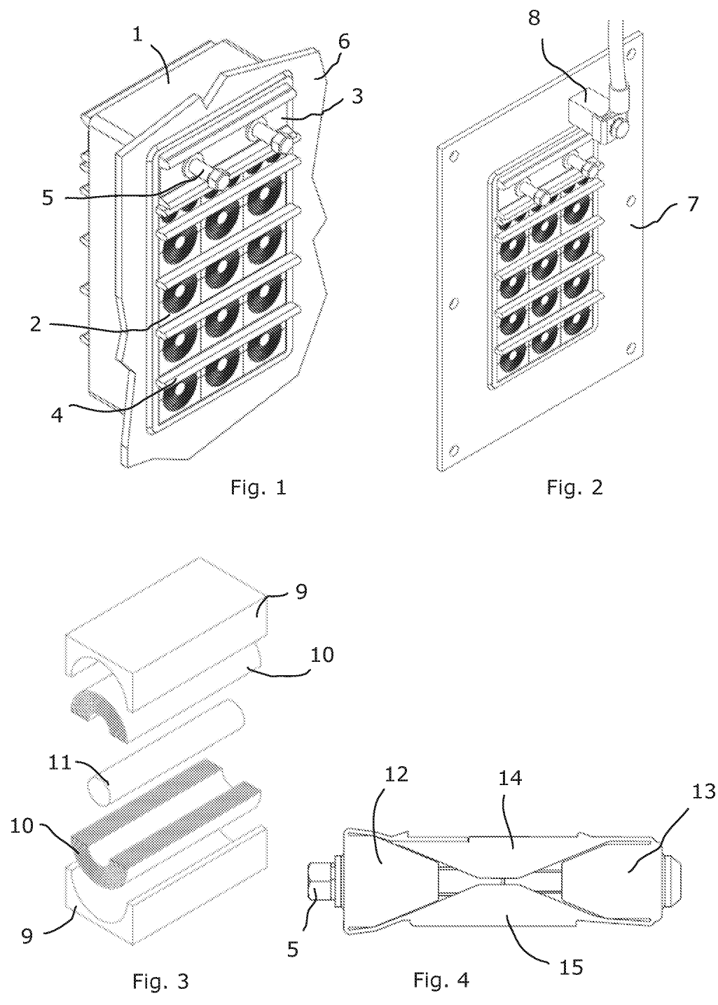

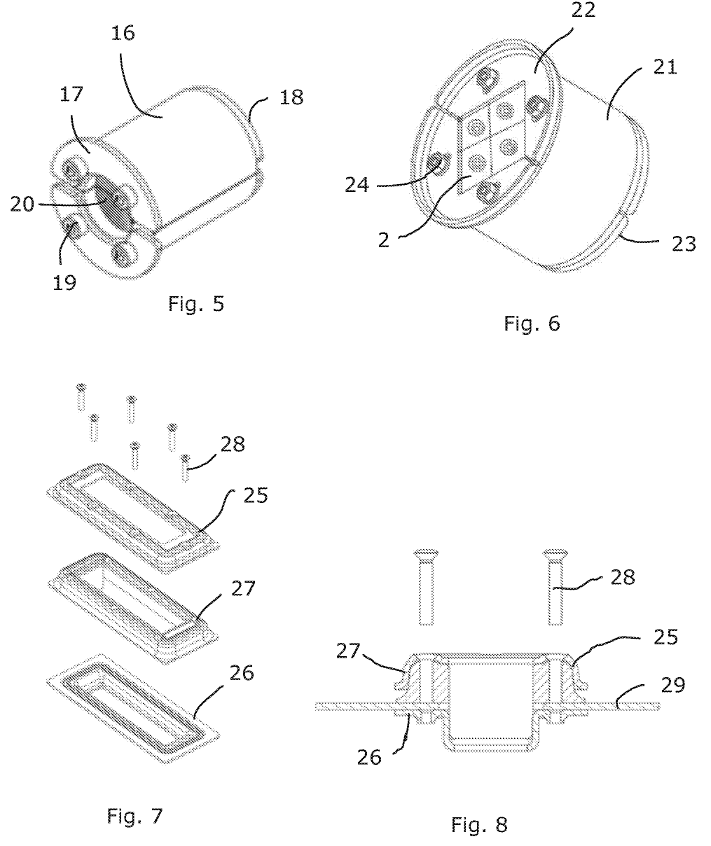

The modules 2 are of use in a transition wherein a number of modules 2 are placed inside a frame 1, which frame 1 is to be received in an opening of a partition 6. In the shown example of FIG. 1, a number of modules 2 are placed in rows inside the frame 1. Stay plates 4 are placed between the rows of modules 2 inside the frame 1. Furthermore, a compression unit 3, here in the form of a wedge, is placed inside the frame 1.

Instead of a module having a number of peelable layers, a corresponding module having no layers may be used. Except for the lack of layers, the module corresponds with the module described above. Each module half has a semi-cylindrical recess whereby an axial through opening will be formed when two module halves are placed on top of each other with the semi-cylindrical recesses facing each other.

In the shown example the frame 1 is welded to the partition. The weld provides for grounding of the frame 1 and the different parts received inside the frame 1. The dissipative parts of the modules 2 and the compression unit 3 are in contact with the frame 1, the stay plates 4 and/or with each other.

In the example of FIG. 2 an alternative frame 7 is shown. The parts received inside this frame 7 correspond with the parts described in connection with the frame of FIG. 1 and will not be described further here. The frame 7 of FIG. 2 is to be bolted to a partition (not shown) and has a separate ground connection connected to a ground point 8 on the frame 7.

The shown compression unit 3 comprises two screws 5 by means of which the compression unit 3 is moveable between a compressing state and a non-compressing state. In the compressing state of the compression unit 3, the modules 2 inside the frame 1, 7 will be compressed, whereby each module 2 will be pressed against a cable or pipe received inside the module 2. The compression unit in form of a wedge comprises four wedge elements 12, 13, 14, 15 made of a dissipative rubber or plastic material. Two of the wedge elements 12, 13 form a first pair, which wedge elements 12, 13 can be moved towards and away from each other by means of the screws 5. The other two wedge elements 14, 15 form a second pair placed on opposite sides of the first pair of wedge elements 12, 13. The first pair of wedge elements 12, 13 is in contact with the second pair of wedge elements 14, 15 along inclined surfaces. In use the first pair of wedges 12, 13 will move axially along the screws 5, while the second pair of wedges 14, 15 will move radially toward and away from the screws 5.

A cylindrical transit or seal may be provided, comprising a cylindrical body 16, a first fitting 17 and a second fitting 18, which first and second fittings 17, 18 are placed at opposite ends of the cylindrical body 16. Screws 19 are provided to move the fittings 16, 17 at opposite ends of the cylindrical body 16 towards each other in order to compress the cylindrical body 16. The cylindrical transit is normally placed directly in an opening of a partition.

The cylindrical body 16 of the cylindrical transit has an axial through opening. The cylindrical body 16 is formed of two halves, each half having a semi-cylindrical recess and said axial through opening is formed when the two halves are placed against each other with the semi-cylindrical recesses facing each other. Peelable layers 20 are placed on the inside of the axial through opening. Said layers 20 are peeled off in order to adapt to the outer diameter of a cable or pipe to be received in the axial through opening. The cylindrical body 16 is made of a dissipative rubber or plastic material. Also the layers 20 may be made of a dissipative material.

In an alternative embodiment the cylindrical transit has a through opening, which is rectangular as seen in end view. Thus, said cylindrical transit comprises a cylindrical body 21, a first fitting 22 and a second fitting 23. The first and second fittings 22, 23 are placed on opposite sides of the cylindrical body 21. The first and second fittings 22, 23 are moved toward each other by means of screw and nut 24 arrangements. The rectangular through opening of the cylindrical transit is to receive one or more modules 2. As stated above at least the base parts of the modules 2 are made of a dissipative rubber or plastic material. Also the cylindrical body 21 is made of a dissipative rubber or plastic material.

In still a further embodiment a transition is formed by a frame having a rectangular, inside of which one or more modules 2 are to be received. The frame comprises two outer frame elements 25, 26 of a relatively hard material, such as metal, and an inner frame element 27 of a compressible material. The outer frame elements 25, 26 are placed on opposite sides of the inner frame element 27. The outer frame elements 25, 26 are moved toward each other by means of screws 28, whereby the inner frame element 27 will be compressed and in turn pressing on modules 2 received in the opening of the frame. The screws 28 are also used for connecting the transition to a partition 29. As stated above at least the base parts 9 of the modules 2 are made of a dissipative rubber or plastic material. Also the inner frame element 27 is made of a dissipative rubber or plastic material.

The modules, wedge and compressible parts of the different embodiments described above can be made of a dissipative material. All metal parts of the different embodiments that are in contact with the dissipative material are connected to earth.

1. Transit for cables and/or pipes through a partition, wherein said transit comprises one or more parts of a rubber or plastic material, wherein at least one of said parts of rubber or plastic material is made of a dissipative rubber or plastic material.

2. The transit of claim 1, wherein the transit comprises modules, which modules comprises two base parts, each having a semi-cylindrical recess, which base parts are made of a dissipative rubber or plastic material.

3. The transit of claim 2, wherein each base part comprises a set of peelable layers placed in the semi-cylindrical recess.

4. The transit of claim 3, wherein the peelable layers are made of a dissipative rubber or plastic material.

5. The transit of claim 2, wherein the transit comprises a frame, inside which frame a number of modules, one or more stay plates and a compression unit is placed.

6. The transit of claim 5, wherein the compression unit comprises wedge elements made of a dissipative rubber or plastic material.

7. The transit of claim 2, wherein the transit comprises a cylindrical body, a first fitting and a second fitting at opposite ends of the cylindrical body, wherein the cylindrical body has a through opening for receiving the one or more modules, and wherein the cylindrical body is made of a dissipative rubber or plastic material.

8. The transit of claim 1, wherein the transit comprises a cylindrical body, a first fitting and a second fitting at opposite ends of the cylindrical body, wherein the cylindrical body has a through opening for receiving a cable or a pipe and wherein the cylindrical body is made of a dissipative rubber or plastic material.

9. The transit of claim 8, wherein the cylindrical body comprises a set of peelable layers placed in the through opening.

10. The transit of claim 9, wherein the peelable layers are made of a dissipative rubber or plastic material.

11. The transit of claim 2, wherein the transit comprises a frame comprising two outer frame elements placed on opposite sides of an inner, frame element, wherein the frame has a through opening for receiving one or more modules, wherein the two outer frame elements are moved toward each other by means of screws in order to compress the inner frame element, and wherein the inner frame element is made of a dissipative rubber or plastic material.

12. The transit of claim 1, wherein any metal part of the transit in contact with a dissipative rubber or plastic material is connected to ground.

13. The transit according to claim 1, wherein the transit is arranged in an explosive environment.
